(19) United States
(12) Patent Application Publication
(10) Pub. No.: US 2025/0245539 A1
(43) Pub. Date: Jul. 31, 2025

(54) METHODS AND CIRCUITS FOR GENERATING ARBITRARY BOSONIC QUANTUM STATES IN A RESONATOR

(71) Applicant: ANYON SYSTEMS INC., Dorval (CA)

(72) Inventors: Clauderic OUELLET-PLAMONDON, Montreal (CA); Gabriel ETHIER-MAJCHER, Montreal (CA); Alireza NAJAFI-YAZDI, Vaudreuil-Dorion (CA)

(21) Appl. No.: 19/040,210

(22) Filed: Jan. 29, 2025

Related U.S. Application Data
(60) Provisional application No. 63/626,405, filed on Jan. 29, 2024.

(51) Int. Cl. G06N 10/40; H10N 60/80

(52) U.S. Cl. CPC G06N 10/40; H10N 60/80

(57) ABSTRACT

A quantum sensing device is selectively operable in a dispersive mode and in a resonant mode to generate arbitrary bosonic quantum states in a storage resonator by changing a coupling rate between the storage resonator and a superconducting qubit via a tunable coupling device.

### CROSS-REFERENCE TO RELATED APPLICATIONS

The present application claims the benefit of U.S. Provisional Patent Application No. 63/626,405 filed on Jan. 29, 2024, the contents of which are hereby incorporated by reference in their entirety.

### TECHNICAL FIELD

The present disclosure generally relates to quantum sensing and more particularly, to circuits and methods for quantum sensing.

### BACKGROUND OF THE ART

Quantum technology encompasses three subfields: computing, communications, and sensing. Quantum computing refers to systems used for computation, which leverages the laws of quantum mechanics to provide exponential performance improvement for some applications. Quantum communications is the secure transfer of quantum information across networks. Quantum sensing is the use of sensors built from quantum systems such that the sensors are orders of magnitude more sensitive than classical sensors.

According to the central limit theorem, the precision of measurements obtained from classical sensors improves only quadratically with an increasing number of measurements. A quantum sensor utilizes properties of quantum mechanics such as quantum entanglement, quantum interference, and quantum state squeezing to surpass this limit in classical sensor technology.

While current quantum sensing technology is suitable for certain purposes, improvements are needed.

### SUMMARY

In accordance with a first broad aspect, there is described herein a quantum sensing device. The device comprises a first storage resonator, a superconducting qubit, a first tunable coupling device coupling the first storage resonator to the superconducting qubit, the first tunable coupling device configured to set a first coupling rate between the first storage resonator and the superconducting qubit, and a plurality of transmission lines configured for applying microwave signals to the first storage resonator, superconducting qubit, and first tunable coupling device. The quantum sensing device is selectively operable in a dispersive mode and in a resonant mode to generate arbitrary bosonic quantum states in the first storage resonator by changing the coupling rate between the first storage resonator and the superconducting qubit via the first tunable coupling device.

In accordance with another broad aspect, there is described herein a method for generating arbitrary bosonic quantum states in a storage resonator. The method comprises tuning a coupling frequency of a first tunable coupling device to one of a first coupling rate and a second coupling rate, the first coupling rate associated with a dispersive approach, the second coupling rate associated with a resonant approach, the first tunable coupling device coupling a first storage resonator to a superconducting qubit, and generating the arbitrary bosonic quantum states in the first storage resonator using a suitable one of the dispersive approach and the resonant approach based on the one of the first coupling rate and the second coupling rate.

In accordance with yet another broad aspect, there is described herein a method for generating arbitrary bosonic quantum states in a storage resonator. The method comprises tuning a coupling frequency of a first tunable coupling device to a first coupling rate, the first tunable coupling device coupling a first storage resonator to a superconducting qubit, generating the arbitrary bosonic quantum states in the storage resonator using a dispersive approach associated with the first coupling rate, tuning the coupling frequency of the first tunable coupling device to a second coupling rate, and generating the arbitrary bosonic quantum state in the storage resonator using a resonant approach associated with the second coupling rate.

### BRIEF DESCRIPTION OF THE DRAWINGS

Reference is now made to the drawings, in which:

FIG. 1 is a schematic diagram of a quantum sensing device;

FIG. 2 is a lumped element representations of an example embodiment of the quantum sensing device of FIG. 1;

FIGS. 3A-3B are graphs of energy levels and coupling rate for the quantum sensing device of FIG. 1 as a function of coupler frequency;

FIG. 4 is a flowchart of a method for generating an arbitrary bosonic quantum state inside a resonator using a resonant approach;

FIG. 5 is a flowchart of a method for generating an arbitrary bosonic quantum state inside a resonator using a dispersive approach;

FIG. 6 is a flowchart of a method for generating an arbitrary bosonic quantum state inside a resonator or a dispersive approach;

FIG. 7 is a lumped element representation of another embodiment of the quantum sensing device; and

FIG. 8 is a block diagram of a system for generating an arbitrary bosonic quantum state inside a resonator.

### DETAILED DESCRIPTION

There are described herein methods and circuits for generating arbitrary bosonic quantum states in a storage resonator. An “arbitrary bosonic quantum state” refers to any possible quantum state of a system composed of bosons, where the state can be a superposition of different combinations of particle numbers in various energy levels, allowing for a wide range of complex configurations beyond just simple single-particle states. A bosonic state can be created with any desired combination of Fock states, including superpositions and entangled states across multiple modes, within the constraints of the system's specific properties. In quantum optics, these states are usually described using Fock states, which represent the number of photons in a given mode, with the ability to create superpositions of different Fock states to represent complex quantum states. Unlike spin systems with discrete states, bosonic systems are considered continuous variable due to the ability to have any number of particles in a given mode. Some examples of non-classical bosonic states are squeezed states, coherent states, and entangled states. Applications of arbitrary bosonic quantum states include quantum computing, quantum communication, and quantum metrology. For example, bosonic states may be used in continuous variable quantum computation schemes, quantum information may be encoded in bosonic states for transmission through optical fibers, and the unique properties of squeezed states can be leveraged for enhanced precision measurements in sensors.

In some embodiments, arbitrary bosonic quantum states are used for quantum sensing. There is described herein a scalable platform for quantum sensing that enables the generation of arbitrary bosonic quantum states in a storage resonator. The architecture is based on superconducting circuits. In some embodiments, the sensor can operate within a 7 to 10 GHz frequency band. Alternatively, it may operate below 7 GHz or above 10 GHZ, as suitable for a given application. The generation of an arbitrary quantum state is defined as the ability to generate any superposition of photon number states (Fock states) inside a storage resonator. This can be achieved by coupling a superconducting qubit to a storage resonator. Example implementations of the storage resonator include a 3D cavity, a co-planar waveguide, an LC resonator, etc. The superconducting qubit may be a transmon, a fluxonium, a charge qubit, a flux qubit, and/or any other two-level system.

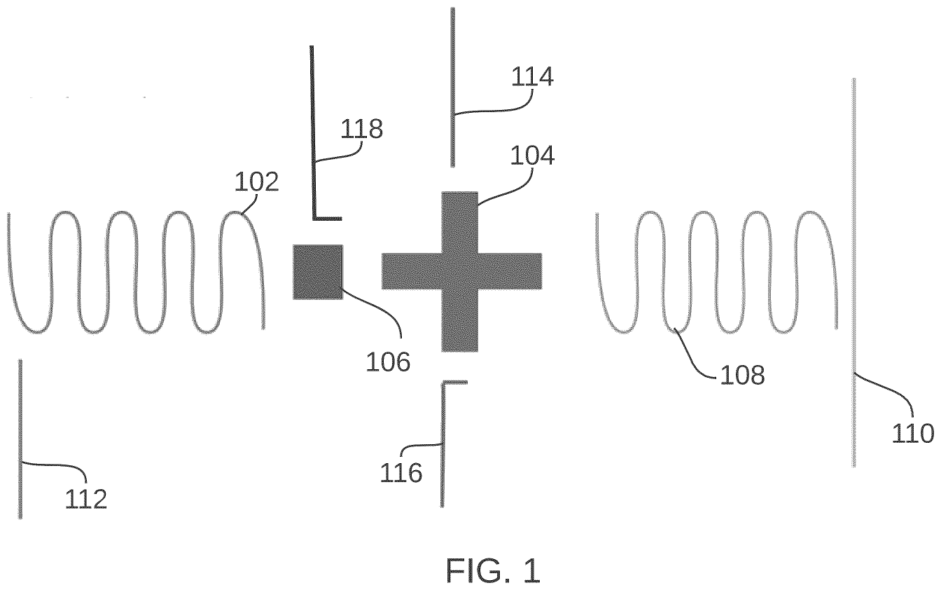

FIG. 1 shows a schematic representation of an example quantum sensing device. A bosonic state is generated in the storage resonator 102, which acts as a single-mode sensor. The storage resonator 102 is capacitively (or inductively) coupled to a tunable superconducting qubit 104 through a coupling device 106. A plurality of transmission lines are coupled to the various devices of the circuit. The transmission lines may be used to perform gating operations, for example on qubit 104, by transmitting drive signals thereto. In this case, the transmission lines may be called “gate lines”. The transmission lines may be used to tune the frequency of a device, such as qubit 104 and/or coupling device 106. In this case, the transmission lines may be called “flux lines”. Separate gate lines and flux lines may be provided, or single transmission lines may be used for both gating and flux-tuning. Gate lines and/or flux lines may be shared by two or more devices, for example a single transmission line may be used to drive a resonator and a qubit. Alternatively or in combination therewith, a given device may have its own transmission line. In the example of FIG. 1, transmission line 112 is capacitively (or inductively) coupled to the storage resonator 102, transmission line 114 is capacitively (or inductively) coupled to the qubit 104. Transmission lines 112, 114 are gate lines for driving the resonator 102 and qubit 104, respectively. Transmission line 116 is inductively coupled to the qubit 104, for tuning the frequency of the qubit 104. Transmission line 118 is inductively coupled to the coupler 106 for tuning the frequency of the coupler 106.

In some embodiments, the qubit 104 may be further coupled to a readout resonator 108 connected to a transmission line 110 to perform qubit readout. The state of the storage resonator 102 may be inferred by measuring the state of the qubit 104.

The quantum sensing device of FIG. 1 may be used to generate arbitrary bosonic quantum states in the storage resonator 102. Moreover, it is selectively operable in a dispersive mode and in a resonant mode to generate arbitrary bosonic quantum states in the storage resonator, as will be explained in more detail below. The following formal definitions for a number of useful quantum states are presented prior to describing the two approaches.

In quantum mechanics, a Fock state (or number state) is a quantum state that is an element of a Fock space with a well-defined number of particles (or photons). For systems where the total number of photons may not be preserved, the number operator counts the number of photons. When a Fock state is applied to the number operator, the eigenvalue is exactly the number of photons, where a^{†}a is the number operator, a^{†} is the creation operator, a is the annihilation operator, n is the number of photons, and |n [symbol] is the Fock state:

$${a}^{†} a \vert n 〉 = n \vert n 〉 ; \qquad ( 1 )$$

Another state applicable to the quantum electrodynamics of resonators is the coherent state. A coherent state has a well-defined phase a and has a Poissonian distribution of photon number with mean |a|². The coherent state can be written as a superposition of Fock states or as generated by applying a displacement operator D(a) on a Vacuum state a, where n is the number of photons:

$$\vert α 〉 = D ( α ) \vert 0 〉 = {e}^{- {\vert α \vert}^{2}} {\sum }_{n = 0}^{∞} \frac{{α}^{n}}{\sqrt{n !}} \vert n 〉 \qquad ( 2 )$$

The coherent state is the closest quantum state to a classical state of the electro-magnetic field. However, a superposition of coherent states such as a cat state ((|a>+|−a>) is not classical. Any arbitrary state |ψ [symbol] of a resonator can be written as a superposition of Fock states with coefficient cₙ:

$$\vert ψ 〉 = {\sum }_{n} {c}_{n} \vert n 〉 \qquad ( 3 )$$

Using only a linear resonator, it is only possible to create coherent states due to the absence of non-linearity necessary to generate arbitrary bosonic states. This can be overcome by coupling the resonator to a qubit and using the latter to engineer photon states in the resonator. At the end of a state preparation sequence, the qubit and the resonator should be decoupled, with the qubit in its ground state |g [symbol] and the resonator in a superposition of Fock states such that the system state ϕ is:

$$\vert ϕ 〉 = \vert g 〉 ⊗ {\sum }_{n} {c}_{n} \vert n 〉 , = \vert g 〉 ⊗ \vert ψ 〉 \qquad ( 4 )$$

The qubit may be viewed as an anharmonic LC oscillator and its two first energy levels may be used to define the qubit states |0> and |1>. The anharmonicity of a qubit may be determined by its charging energy (inversely proportional to its capacitance). A qubit may be coupled (e.g. capacitively coupled) to a transmission line resonator by bringing the superconducting island of each device (i.e. the qubit and the resonator) close to one another. The interaction between the qubit and the resonator may be described by the following Hamiltonian H_{JC}:

$${H}_{JC} / ℏ = {ω}_{s} {a}^{†} a + {ω}_{q} {b}^{†} b + g ( {a}^{†} b + {ab}^{†} ) . \qquad ( 5 )$$

In equation (5), wₛ and w_{q} are resonance frequencies of the resonator and the qubit, g is the coupling rate, a, b are annihilation operators for the resonator and the qubit, respectively, and a^{†}, b^{†} are the creation operators for the resonator and the qubit, respectively. This Hamiltonian is similar to the Jaynes-cummings model but with more than two levels for the qubit.

When the qubit is resonant with the storage resonator, the rabi rate Ω(n) between the qubit and the resonator is photon dependent, where g is the coupling rate, n is the photon count:

$$Ω ( n ) = 2 \sqrt{n + 1} g \qquad ( 6 )$$

The eigenstates |ψₙ [symbol] of the system are the superposition of n photons in the resonator with the qubit in its excited state (|n, e>) and n+1 photons in the resonator, and the qubit in its ground state (|n−1, g>), with coefficients cₙ and cₙ₊₁:

$$\vert {ψ}_{n} 〉 = {c}_{n} \vert n , e 〉 + {c}_{n + 1} \vert n + 1 , g 〉 \qquad ( 7 )$$

Having set out some formal definitions in equations (1) to (7), the two approaches to generate bosonic arbitrary quantum states, referred to as the “resonant approach” and the “dispersive approach”, may now be described. The resonant approach for generating arbitrary bosonic quantum states in a storage resonator takes advantage of equations (6) and (7). The system is first initialized in its ground state (zero photons in the resonator, and the qubit is in its ground state, |0, g>) and the qubit is detuned from the resonator. The qubit is then loaded with a single photon by applying a microwave pulse on a transmission line associated with the qubit (e.g. performing an X or Y gate). Next, the qubit is brought into resonance with the storage resonator, which causes the photon to be swapped from the qubit to the resonator. The resulting state in the resonator is a Fock state with a single photon. It is possible to correct for the phase by adding delays between pulses. Repeating the process N times allows to create N Fock states |n>, thus generating arbitrary bosonic quantum states in the storage resonator.

Using the dispersive approach, the qubit is far detuned from the resonator, D>>g, where D=wₛ−w_{q}. The Hamiltonian H_{disp} in the dispersive regime can be written as:

$${H}_{disp} / ℏ = {ω}_{q} {b}^{†} b + {ω}_{s} {a}^{†} a + 2 χ {a}^{†} {ab}^{†} b \qquad ( 8 )$$

In equation (8), c is the dispersive shift, wₛ and w_{q} are resonance frequencies of the resonator and the qubit, a, b are annihilation operators for the resonator and the qubit, and a^{†}, b^{†} are the creation operators for the resonator and the qubit, respectively. In this regime, the resonator frequency is shifted by 2c depending on whether the qubit is in state |1> or |0>.

From the qubit viewpoint, the dispersive shift leads to an AC-Stark shift of the qubit resonance frequency ω_{q}, where n is number of photons, c is the dispersive shift, and a, a^{†} are annihilation and creation operators for the resonator, respectively:

$${ω}_{q} ( n ) = {ω}_{q} + 2 χ {a}^{†} a \qquad ( 9 )$$

In the so-called strong dispersive regime, where the dispersive shift is larger than the dissipative losses, the spectrum of the qubit becomes a series of peaks separate by 2c, where each peak is associated with a particular Fock state in the resonator. The amplitude of the peaks depends on the probability of finding |N> photons in the resonator.

Arbitrary quantum states can be generated in the storage resonator when the system operates in the strong dispersive regime. The phase of a single Fock state |n> in the storage resonator can be modified by driving the qubit at the frequency ω_{q}(n) (equation (9)). Specifically, the phase of the Fock state is determined by the area spanned by the trajectory of the qubit on its Bloch sphere when driven. By starting and ending the drive sequence with the qubit in its ground state, the accumulated phase is fully transferred to the Fock state of the storage resonator. This operation is called a SNAP gate for Selective Number-dependent Arbitrary Phase. In general, if the resonator is prepared with a coherent state (as per equation (2)), a gate pulse with many frequency components can be applied to the qubit to simultaneously modify the phase of every Fock component of the coherent state. It will be understood that operating in the dispersive mode may comprise a conditional displacement operator, whereby the resonator is driven conditionally on the qubit state or a conditional gate, whereby the qubit is driven conditionally on the resonator state.

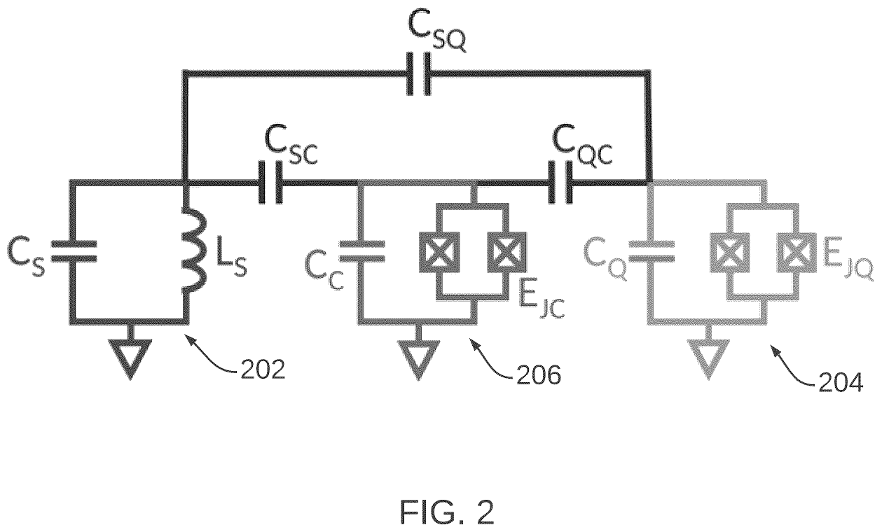

The resonant approach and the dispersive approach may both be applied to the quantum sensing device of FIG. 1. A first embodiment of a lumped element representation of the schematic of FIG. 1 is shown in FIG. 2. A resonator 202 is modeled as an LC oscillator. A coupler 206 and a qubit 204 are each depicted as frequency-tunable qubits. The tunable coupler 206 is capacitively coupled to the resonator 202 by capacitance C_{SC} and to the qubit 204 by capacitance C_{QC}. The qubit 204 and the resonator 202 are coupled by capacitance C_{SQ}.

The Hamiltonian of the circuit of FIG. 2 is written as:

$$H = {H}_{0} + {H}_{dir} + {H}_{ind} \qquad ( 10 )$$

$${H}_{0} = {ω}_{s} {a}^{†} a + {\sum }_{i = q , c} [ {ω}_{i} {b}_{i}^{†} {b}_{i} + \frac{{η}_{i}}{2} {b}_{i}^{†} {b}_{i}^{†} {b}_{i} {b}_{i} ] \qquad ( 11 )$$

$${H}_{ind} = {g}_{sc} ( {a}^{†} {b}_{c} + {ab}_{c}^{†} ) + {g}_{qc} ( {b}_{q}^{†} {b}_{c} + {b}_{q} {b}_{c}^{†} ) \qquad ( 12 )$$

$${H}_{dir} = {g}_{sq} ( {a}^{†} {b}_{q} + {ab}_{q}^{†} ) \qquad ( 13 )$$

In equations (10)-(13), a^{†} and a are creation and annihilation operators of the storage resonator, b_{q} and b_{q}^{†} are annihilation and creation operators of the qubit, b_{c} and b_{c}^{†} are creation and annihilation operators of the coupler, wₛ, w_{q}, and w_{c} are the frequencies of the resonator, qubit, and coupler respectively, and h is the anharmonicity. The coupling constants g_{sc}, g_{qc}, and g_{sq} are a function of the relevant coupling capacitances from FIG. 2 and are calculated by inverting the capacitance matrix of the system. The coupler 206 and the qubit 204 are described as anharmonic oscillators and the capacitive coupling between each element (direct and indirect) leads to Jaynes-cummings-like interaction terms.

The tunable coupler 206 is used to set the circuit such that the qubit 204 and the resonator 202 are either in resonance or in a dispersive regime. Indeed, the effective coupling rate between the qubit 204 and the resonator 202 is determined based on the coupling rate through C_{SQ} and the coupler-mediated coupling rate that depends on the magnitudes of C_{SC} and C_{QC} as well as on the frequency of the coupler 206.

For each approach (i.e. dispersive or resonant), a target coupling rate between the qubit 204 and the storage resonator 202 is selected. Next, using the equations below, the corresponding coupling capacitance is determined. The coupling rate g between the capacitively coupled qubit 204 and resonator 202 is:

$$Ω = 2 g = \frac{\sqrt{{ω}_{S} {ω}_{Q}} {C}_{SQ}}{\sqrt{( {C}_{R} + {C}_{SQ} ) ( {C}_{Q} + {C}_{SQ} )}} \qquad ( 14 )$$

where C_{Q}, C_{R}, and C_{SQ} are qubit, resonator and coupling capacitances, respectively. A transmission line quarter wave resonator can be modelled as an effective LC resonator with capacitance C_{S}:

$${C}_{S} = \frac{π}{4 {ω}_{S} {Z}_{S}} \qquad ( 15 )$$

where Z_{S} is the resonator impedance and wₛ²=1/(L_{S}C_{S}). The dispersive shift between a Transmon qubit and a resonator is:

$$χ = \frac{{g}^{2}}{Δ ( 1 + Δ / η )} \qquad ( 16 )$$

where g is the coupling strength from eq. (14), D=wₛ−w_{q} is the frequency detuning and h is the transmon anharmonicity which is negative.

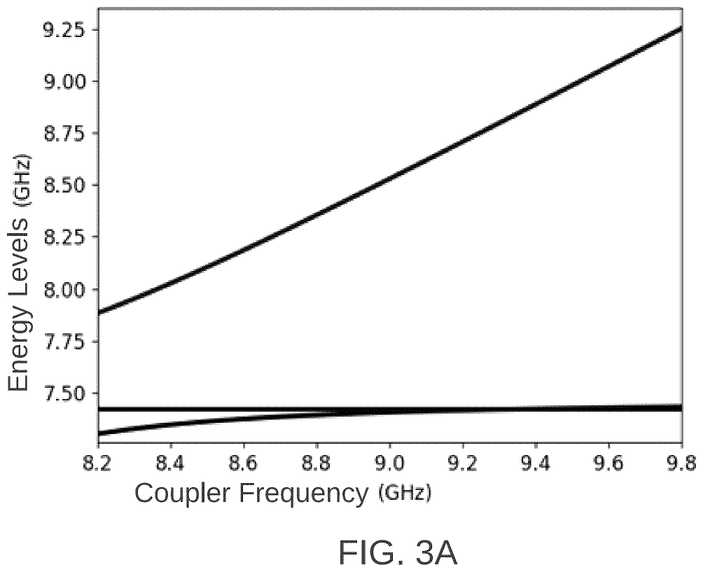

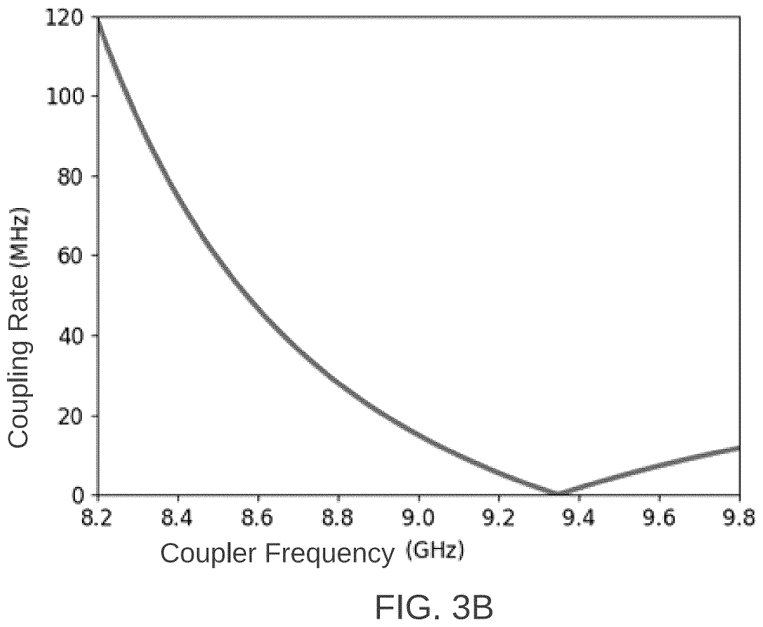

The Hamiltonian of a resonator-coupler-qubit system may be simulated to determine the coupling capacitances for the coupler. FIG. 3A illustrates the energy levels as a function of the coupler frequency. FIG. 3B illustrates coupling rates as a function of the coupler frequency. In this example, the single photon coupling rate can be tuned from almost zero to more than 100 MHz by lowering the coupler frequency.

The embodiment illustrated in FIG. 2 may be used to selectively perform the resonant approach and the dispersive approach with a single circuit design. Indeed, the frequency-tunable coupler 206 is used to set the target coupling rate between the resonator 202 and the qubit 204 that is appropriate for the selected approach to generate arbitrary bosonic quantum states in the resonator 202.

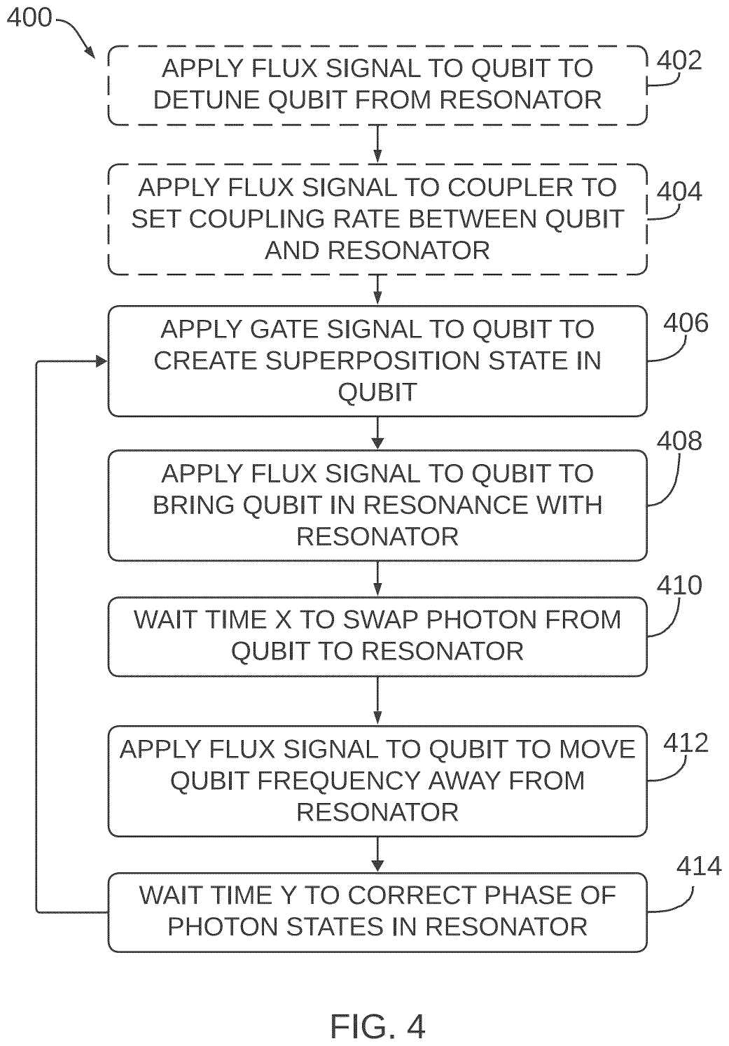

With reference to FIG. 4, there is illustrated an example embodiment of a method 400 for generating arbitrary bosonic quantum states in a resonator using the resonant approach. At step 402, a flux signal is applied to a qubit to detune the qubit from the resonator. Step 402 may be omitted if the qubit and resonator are already detuned. At step 404, a flux signal is applied to a coupler to set the coupling rate between the qubit and the resonator. Step 404 may be omitted if the coupling rate between the qubit and the resonator has already been set prior to method 400 beginning. At step 406, a gate signal is applied to the qubit to create a superposition state in the qubit. At step 408, a flux signal is applied to the qubit to bring the qubit in resonance with the resonator. At step 410, time X elapses to allow the photon to swap from the qubit to the resonator. At step 412, a flux signal is applied to the qubit to move the qubit frequency away from the resonator. At step 414, time Y elapses to correct the phase of photon states in the resonator. Steps 406-414 may be repeated to generate additional arbitrary bosonic states in the resonator.

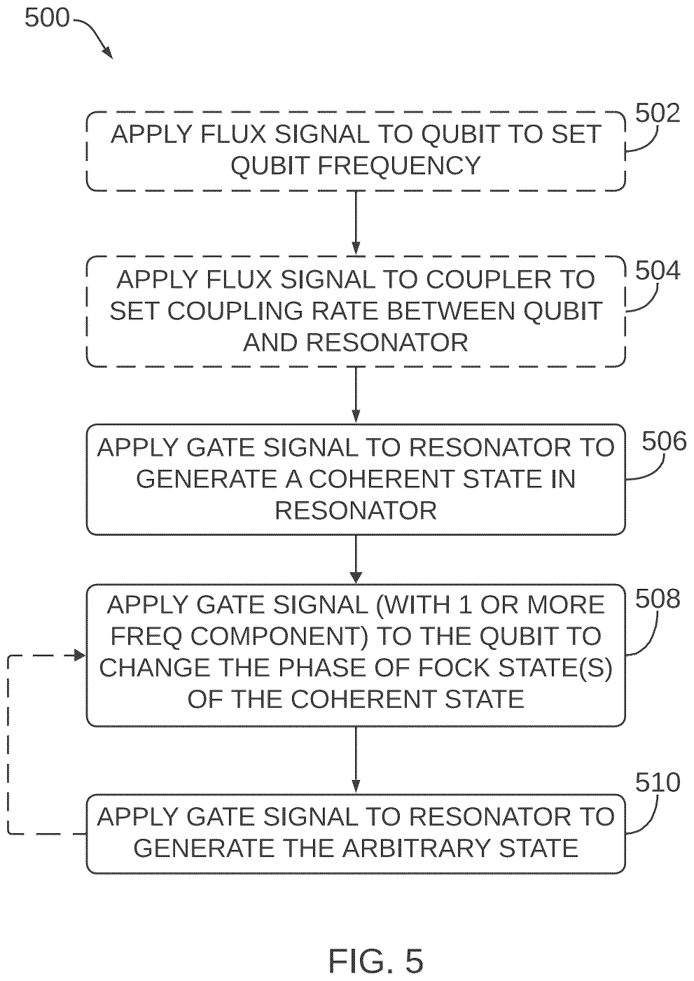

With reference to FIG. 5, there is illustrated an example embodiment of a method 500 for generating arbitrary bosonic quantum states in a resonator using the dispersive approach. At step 502, a flux signal is applied to the qubit to set the qubit frequency. Step 502 may be omitted if the qubit frequency has already been set. At step 504, a flux signal is applied to the coupler to set the coupling rate between the qubit and the resonator. Step 504 may be omitted if the coupling rate between the qubit and the resonator has already been set prior to method 500 beginning. At step 506, a gate signal is applied to the resonator to generate a coherent state in the resonator. At step 508, a gate signal (with 1 or more frequency component) is applied to the qubit to change the phase of the Fock state(s) of the coherent state. At step 510, a gate signal is applied to the resonator to generate the arbitrary state. In some embodiments steps 508-510 are repeated to optimize the arbitrary state.

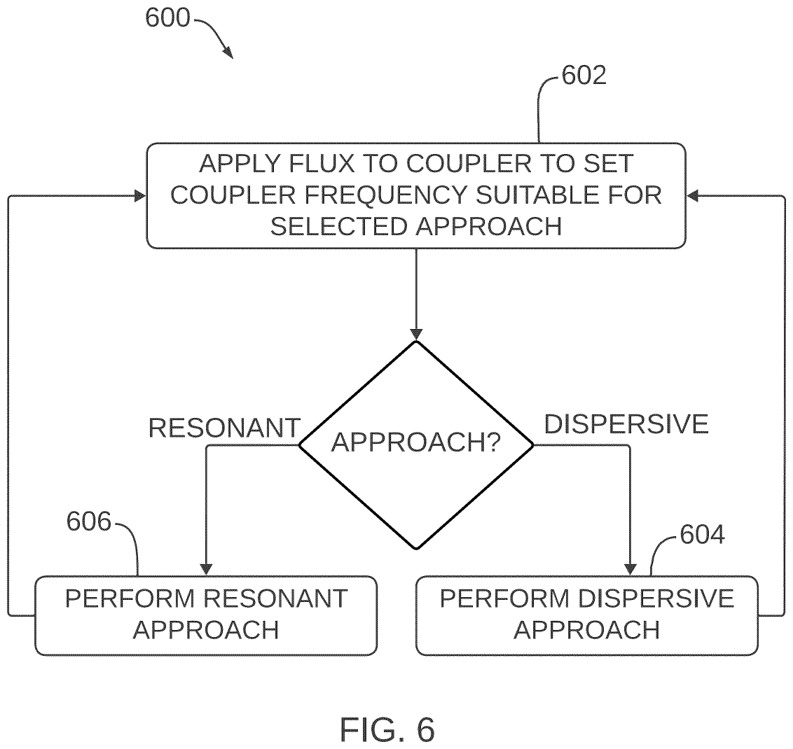

With reference to FIG. 6, there is illustrated a method 600 for selectively applying the resonant approach and the dispersive approach to generate arbitrary bosonic quantum states in a resonator. At step 602, a flux signal is applied to the coupler to set the coupler frequency to a value suitable for the selected approach. If the coupler frequency is set for the dispersive approach, step 604 is then performed. If the coupler frequency is set for the resonant approach, step 606 is then performed. The method 600 may then loop back to step 602 such that the coupler frequency is set to perform the same or a different approach. In some embodiments, step 604 corresponds to method 500 (with step 504 omitted). In some embodiments, step 606 corresponds to method 400 (with step 404 omitted).

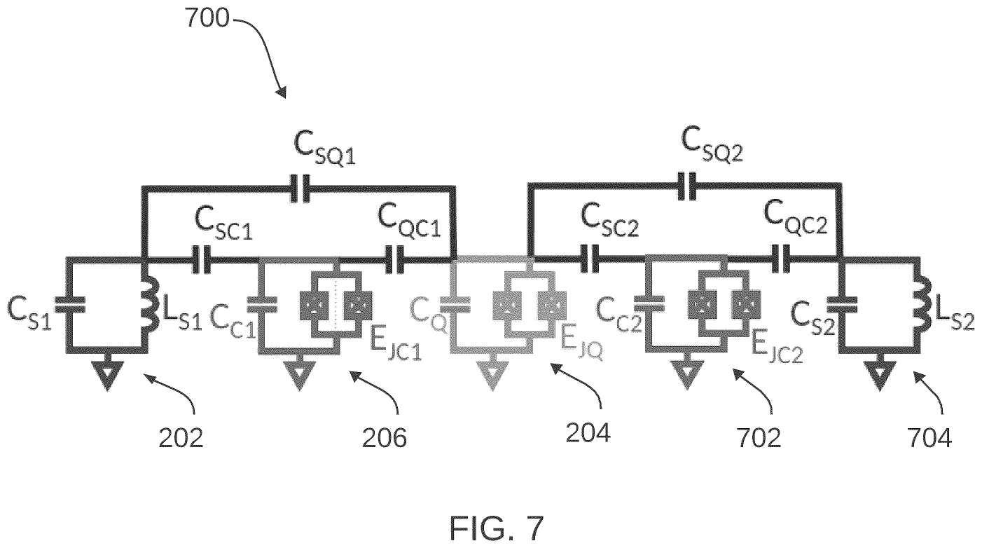

With reference to FIG. 7, there is illustrated a circuit 700 whereby a second coupler 702 and a second resonator 704 are added to the circuit of FIG. 2. This design enables the control of two resonators 202, 704 by selectively tuning one coupler 206 or 702 while the other coupler 702 or 206 is off. When both couplers 206, 702 are on, the simultaneous dispersive interaction of the two resonators 202, 704 on the qubit 204 will induce a joint frequency shift. Such a state can be used to generate coupling between two resonators 202, 704 to create entanglement. Frequency tuning of the qubit 204 is not required with this approach, such that the frequency tunable qubit 204 may be replaced with a fixed frequency qubit.

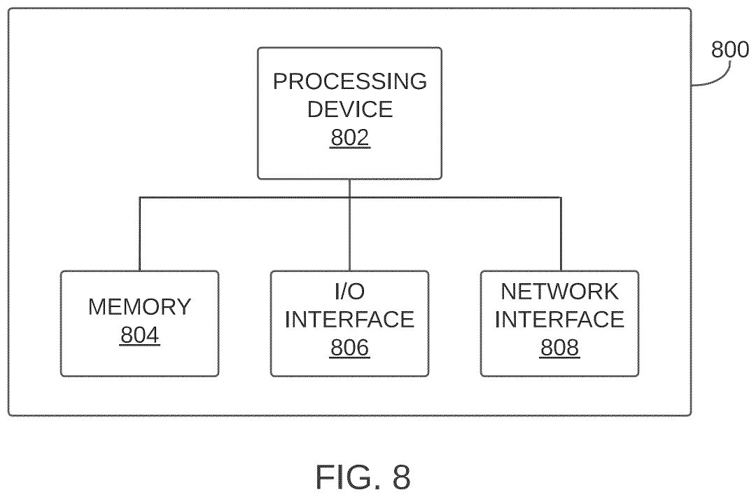

In some embodiments, the methods 400, 500, 600, are embodied as a set of instructions stored on a non-transitory computer-readable medium. The instructions are executable by a processing device. FIG. 8 is an example system 800 for implementing the methods 400, 500, 600 in accordance with various embodiments. The system 800 can be provided as part of a classical computer that interfaces with a quantum device, such as a quantum sensor or a quantum computer. The system 800 can also be provided as a set of control electronics that interface with a quantum device.

As depicted, the system 800 can include one or more of a processing device 802, a memory 804, an input/output (I/O) interface 806, and a network interface 808. The processing device(s) 802 may be an Intel or AMD x86 or x64, PowerPC, ARM processor, or the like. In some embodiments, the processing device(s) 802 is a field programmable gate array (FPGA) or an application specific integrated circuit (ASIC), provided on one or more board. Each memory 804 may include a suitable combination of computer memory that is located either internally or externally such as, for example, random-access memory (RAM), read-only memory (ROM), integrated memory, compact disc read-only memory (CDROM). In some embodiments, both on-board high bandwidth memory and off-board memory are provided.

Each I/O interface 806 enables the system 800 to interconnect with one or more other devices, such as a host computer, a network switch, and the like. The I/O interface 806 can be used, for example, for receiving instructions for the processing device 802. Various communication protocols may be used for communicating with the system 800 through the I/O interface 806, such as but not limited to Peripheral Component Interconnect Express (PCIe), Ethernet, InfiniBand, and the like.

Each network interface 808 enables the system 800 to communicate with other components, for example, through an API to exchange data with other components, to access and connect to network resources, to serve applications, and perform other computing applications by connecting to a network (or multiple networks) capable of carrying data including the Internet, Ethernet, plain old telephone service (POTS) line, public switch telephone network (PSTN), integrated services digital network (ISDN), digital subscriber line (DSL), coaxial cable, fiber optics, satellite, mobile, wireless (e.g., Wi-Fi, WiMAX), SS7 signaling network, fixed line, local area network, wide area network, and others.

The described embodiments and examples are illustrative and non-limiting. Practical implementation of the features may incorporate a combination of some or all of the aspects, and features described herein should not be taken as indications of future or existing product plans. Applicant partakes in both foundational and applied research, and in some cases, the features described are developed on an exploratory basis.

Although the embodiments have been described in detail, it should be understood that various changes, substitutions and alterations can be made herein without departing from the scope. Moreover, the scope of the present application is not intended to be limited to the particular embodiments of the process, machine, manufacture, composition of matter, means, methods and steps described in the specification.

As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized. Accordingly, the appended claims are intended to include within their scope such processes, machines, manufacture, compositions of matter, means, methods, or steps.

1. A quantum sensing device comprising:
a first storage resonator;
a superconducting qubit;
a first tunable coupling device coupling the first storage resonator to the superconducting qubit, the first tunable coupling device configured to set a first coupling rate between the first storage resonator and the superconducting qubit; and
a plurality of transmission lines configured for applying microwave signals to the first storage resonator, superconducting qubit, and first tunable coupling device;
wherein the quantum sensing device is selectively operable in a dispersive mode and in a resonant mode to generate arbitrary bosonic quantum states in the first storage resonator by changing the coupling rate between the first storage resonator and the superconducting qubit via the first tunable coupling device.

2. The quantum sensing device of claim 1, wherein the superconducting qubit is a frequency tunable qubit.

3. The quantum sensing device of claim 1, wherein the first storage resonator is capacitively coupled to the superconducting qubit through the first tunable coupling device.

4. The quantum sensing device of claim 1, further comprising a readout resonator coupled to the superconducting qubit.

5. The quantum sensing device of claim 1, wherein the plurality of transmission lines comprises:
a first transmission line coupled to the first storage resonator;
a second transmission line coupled to the superconducting qubit;
a third transmission line coupled to the superconducting qubit; and
a fourth transmission line coupled to the first tunable coupling device.

6. The quantum sensing device of claim 5, wherein the first transmission line is capacitively coupled to the first storage resonator, and the second transmission line is capacitively coupled to the superconducting qubit.

7. The quantum sensing device of claim 5, wherein the third transmission line is inductively coupled to the superconducting qubit, and the fourth transmission line is inductively coupled to the first tunable coupling device.

8. The quantum sensing device of claim 1, wherein the first tunable coupling device is a qubit.

9. The quantum sensing device of claim 1, further comprising:
a second storage resonator; and
a second tunable coupling device coupling the second resonator to the superconducting qubit, the second coupling device configured to set a second coupling rate between the second storage resonator and the superconducting qubit.

10. A method for generating arbitrary bosonic quantum states in a storage resonator, the method comprising:
tuning a coupling frequency of a first tunable coupling device to one of a first coupling rate and a second coupling rate, the first coupling rate associated with a dispersive approach, the second coupling rate associated with a resonant approach, the first tunable coupling device coupling a first storage resonator to a superconducting qubit; and
generating the arbitrary bosonic quantum states in the first storage resonator using a suitable one of the dispersive approach and the resonant approach based on the one of the first coupling rate and the second coupling rate.

11. The method of claim 10, wherein tuning the coupling frequency of the first tunable coupling device comprises applying a microwave signal to a transmission line associated with the tunable coupling device, the flux signal having parameters selected for the one of the first coupling rate and the second coupling rate.

12. The method of claim 10, further comprising applying a microwave signal to the superconducting qubit prior to tuning the coupling frequency of the first tunable coupling device, the microwave signal selected to detune a frequency of the superconducting qubit from a frequency of the first storage resonator.

13. The method of claim 10, further comprising applying a microwave signal to the superconducting qubit prior to tuning the coupling frequency of the first tunable coupling device, the microwave signal selected to set a frequency of the superconducting qubit.

14. The method of claim 10, wherein the suitable one of the dispersive approach and the resonant approach is the resonant approach, and generating the arbitrary bosonic quantum states comprises:
creating a superconducting state in the superconducting qubit;
placing the superconducting qubit and the first storage resonator in resonance to swap a photon from the superconducting qubit to the first storage resonator; and
adjusting a phase of the swapped photon in the first storage resonator.

15. The method of claim 10, wherein the suitable one of the dispersive approach and the resonant approach is the dispersive approach, and generating the arbitrary bosonic quantum states comprises driving the first storage resonator conditionally on a state of the superconducting qubit.

16. The method of claim 10, wherein the suitable one of the dispersive approach and the resonant approach is the dispersive approach, and generating the arbitrary bosonic quantum states comprises driving the superconducting qubit conditionally on a state of the first storage resonator.

17. The method of claim 10, further comprising:
tuning a coupling frequency of a second tunable coupling device to one of the first coupling rate and the second coupling rate, the second tunable coupling device coupling a second storage resonator to the superconducting qubit; and
generating the arbitrary bosonic quantum states in the second storage resonator using a suitable one of the dispersive approach and the resonant approach based on the one of the first coupling rate and the second coupling rate.

18. A method for generating arbitrary bosonic quantum states in a storage resonator, the method comprising:
tuning a coupling frequency of a first tunable coupling device to a first coupling rate, the first tunable coupling device coupling a first storage resonator to a superconducting qubit;
generating the arbitrary bosonic quantum states in the storage resonator using a dispersive approach associated with the first coupling rate;
tuning the coupling frequency of the first tunable coupling device to a second coupling rate; and
generating the arbitrary bosonic quantum state in the storage resonator using a resonant approach associated with the second coupling rate.

19. The method of claim 18, further comprising applying a microwave signal to the superconducting qubit prior to tuning the coupling frequency of the first tunable coupling device to the second coupling rate, the microwave signal selected to detune a frequency of the superconducting qubit from a frequency of the first storage resonator.

20. The method of claim 19, further comprising applying a microwave signal to the superconducting qubit prior to tuning the coupling frequency of the first tunable coupling device to the first coupling rate, the microwave signal selected to set a frequency of the superconducting qubit.
